(19) United States
(12) Patent Application Publication
(10) Pub. No.: US 2025/0324810 A1
(43) Pub. Date: Oct. 16, 2025

(54) TAPERED LIGHT ABSORPTION STRUCTURE FOR INTEGRATED CIRCUIT PHOTODETECTOR

(71) Applicant: Taiwan Semiconductor Manufacturing Company, Ltd., Hsinchu (TW)

(72) Inventors: Wen-Shun Lo, Zhudong Township (TW); Shao-Da Wang, New Taipei City (TW); Sheng Kai Yeh, Taichung City (TW); Chi-Yuan Shih, Hsinchu (TW); Yingkit Felix Tsui, Cupertino, CA (US); Shih-Fen Huang, Jhubei (TW)

(21) Appl. No.: 18/635,478

(22) Filed: Apr. 15, 2024

(51) Int. Cl. H01L 31/0352; H01L 31/0232; H01L 31/0288; H01L 31/18

(52) U.S. Cl. CPC H10F 77/147; H10F 71/121; H10F 77/1223; H10F 77/413

(57) ABSTRACT

Some embodiments relate to an integrated circuit device that includes an optical coupler structure and a photodiode structure over a substrate, where the photodiode structure is laterally adjacent the optical coupler structure. The photodiode structure includes a doped structure including a first semiconductor material, and a light absorption structure includes a second semiconductor material, contacts the doped structure, and is aligned with the optical coupler structure. The light absorption structure includes a first region proximal to the optical coupler structure and having a first width, a second region distal from the optical coupler structure and having a second width greater than the first width, and a tapered region connecting the first region to the second region. The tapered region has a first end adjacent the first region and a second end adjacent the second region. The first end has the first width and the second end has the second width.

### BACKGROUND

Silicon photonics is the study and application of photonic systems that use silicon as an optical medium. Use of silicon photonics thus may facilitate the construction of efficient information processing integrated circuit (IC) devices due to their compatibility with complementary metal-oxide-semiconductor (CMOS) technology. Such low-cost, high-yield devices are employable in several application areas, including, but not limited to, microwave photonics, optical sensing, optical communications, telecommunications, and high-performance computing. In such areas, photodetectors (PDs) may be used to detect information provided in photon signals. Accordingly, high-speed, high-power PDs in IC devices are in substantial demand, and thus are a particular focus of research and development.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic plan view of some embodiments of a photodiode structure employing a tapered light absorption structure, according to the present disclosure.

FIGS. 1B and 1C illustrate qualitative graphs of light intensity and number of electron/hole pairs, respectively, of some embodiments of a photodiode structure, according to the present disclosure.

FIG. 2A is a plan view of some embodiments of a photodiode structure employing a tapered light absorption structure, according to the present disclosure.

FIGS. 2B through 2D illustrate structural side views of some embodiments of the photodiode structure of FIG. 2A at corresponding positions therein, according to the present disclosure.

FIGS. 3A through 3O illustrate cross-sectional views of some embodiments of an IC device including a photodiode structure employing a tapered light absorption structure at multiple stages of fabrication, according to the present disclosure.

FIG. 4 illustrates a methodology of forming some embodiments of the photodiode structure of FIGS. 3A through 3O, according to the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for case of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some photodetectors (PDs), such as photodiodes, a rectangular structure of semiconductor material, such as germanium (Ge), may be employed as a light absorption component. A major axis (e.g., a length) of the rectangular structure may be aligned along a central axis of an optical coupler (e.g., a structure that may convert a spot size of light from a waveguide to a spot size corresponding with the PD), and a minor axis (e.g., a width) of the rectangular structure may be transverse to the optical coupler. Based on the rectangular structure of the light absorption component, the PD may possess a particular radio-frequency (RF) behavior in which higher photocurrents are associated with narrower three-decibel (3-dB) (e.g., half-power) bandwidths.

To provide a wider 3-dB bandwidth to facilitate a greater range of frequencies at which the PD may operate, the width of the rectangular structure may be decreased to reduce the light absorption capability of the structure, particularly at the front or light-receiving end of the structure, thus reducing the number of electron-hole pairs being generated. The reduction in electron-hole pairs may lead to a lower space charge screening effect, and thus a wider 3-dB bandwidth for the PD. However, the decreased width of the rectangular structure may also decrease the saturation current of the PD. Consequently, at a high level of photon power, the light absorption component may absorb significantly fewer than all photons being received. As a result, modification of the width of the rectangular light absorption structure results in a tradeoff between the bandwidth (e.g., high-speed) and saturation current (e.g., high-power) capabilities of the PD.

To address these issues, the present disclosure provides some embodiments of a photodetector that employs a tapered light absorption structure. In some embodiments, the light absorption may have three regions: a first region of a first width at an end of the light absorption structure at which light is received; a second region of a second width at an opposing end of the light absorption structure, where the second width is greater than the first width, and a tapered region connecting the first and second regions. By employing a light absorption structure that employs such a tapered profile, the first region with the lower width, at which the intensity of received light is highest, is associated with a reduced amount of light absorbed, thus supporting a relatively wide 3-dB bandwidth at the first region. At the second region, at which the intensity of received light is lower, the second region with the greater width supports a higher saturation current compared to the first region. Thus, in some embodiments, the combined effect of the tapered light absorption structure is a relatively wide 3-dB bandwidth and a relatively high saturation current.

Accordingly, use of some embodiments of an IC device employing a PD with a tapered light absorption structure may provide a high-power, high-speed PD that supports enhanced performance for microwave photonics, optical sensing, optical communications, and other applications to which silicon photonics platforms are directed.

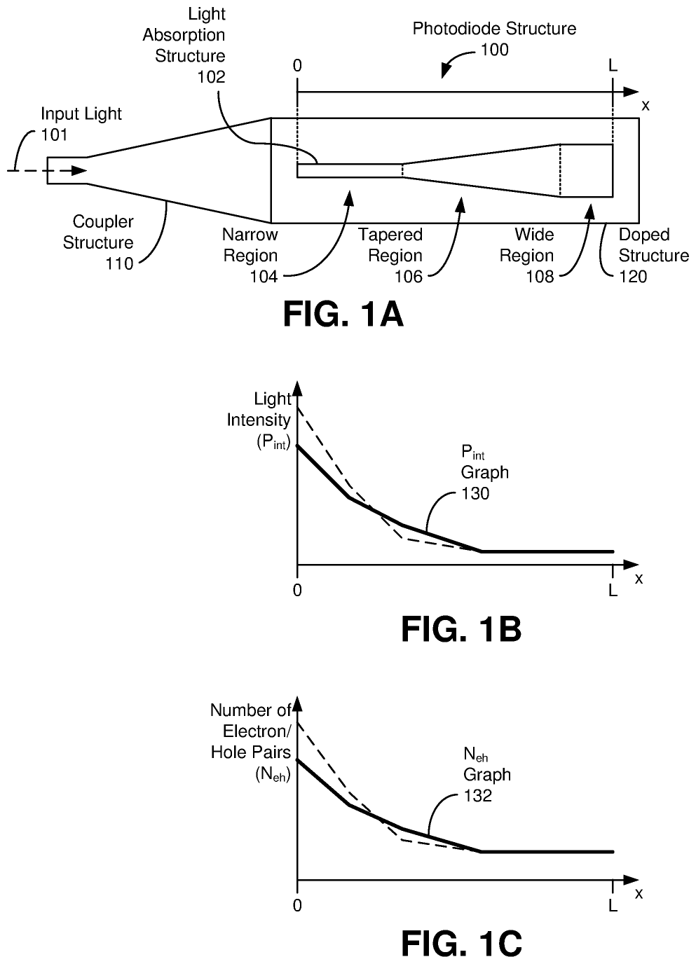

FIG. 1A is a schematic plan view of some embodiments of a photodetector (e.g., a photodiode structure 100) employing a tapered light absorption structure 102, according to the present disclosure. As shown, photodiode structure 100 receives input light 101 by way of an optical coupler structure 110 adjacent thereto. As depicted, optical coupler structure 110 may operate as a spot size converter from a size associated with a waveguide to a size associated with photodiode structure 100. However, other types of optical coupler structures aside from that specifically shown in FIG. 1A and elsewhere herein that provides light to photodiode structure 100 may be used in other embodiments.

Photodiode structure 100 may include a doped structure 120 (e.g., a semiconductor layer including n-doped and p-doped regions, as described in greater detail below) and a light absorption structure 102. In some embodiments, light absorption structure 102 is generally tapered by having a relatively small width at an input end (e.g., at which input light 101 is received from optical coupler structure 110) to a relatively larger width at an end opposite the input end. More specifically, in some embodiments, light absorption structure 102 may have a first region 104 (e.g., a narrow region 104) and a second region 108 (e.g., a wide region 108) at opposing ends, with a tapered region 106 connecting the first region 104 and the second region 108 along the length of light absorption structure 102. In some embodiments, as discussed above, such a tapered profile for light absorption structure 102 may provide both high-power and high-speed performance for corresponding photodiode structure 100, which may be advantageous when used within a silicon photonics platform.

FIGS. 1B and 1C illustrate qualitative graphs of light intensity and number of electron/hole pairs, respectively, of some embodiments of a photodiode structure 100, according to the present disclosure. More specifically, FIG. 1B is a light intensity (Pint) graph 130 along a length L of an x-direction (e.g., a direction along which input light 101 enters photodiode structure 100), as indicated in FIG. 1A. Similarly, FIG. 1C is a number of electron-hole pairs (Nₑₕ) graph 132 along length L of the x-direction. In both FIGS. 1B and 1C, the solid graph line depicts the indicated characteristic associated with light absorption structure 102 of FIG. 1A, while the dashed line illustrates the same characteristic for a theoretical rectangular (e.g., non-tapered) light absorption structure. Accordingly, in FIG. 1B, the curvature of light intensity Pint graph 130 may be moderated such that Pint is relatively low at a low range of x, relatively high through some intermediate range of x, and an expected level at a high range of x up to length L. The same moderated or smoothed curvature is depicted for Nₑₕ graph 132 of FIG. 1C. Consequently, as described above, first region 104 of light absorption structure 102, with its lower width, may cause a reduced amount of light absorbed at and near the input end of light absorption structure, thus facilitating a relative wide 3-dB bandwidth at first region 104. At second region 108, at which the intensity of received light is lower, second region 108 with greater width supports a higher saturation current compared to first region 104. As a result, in some embodiments, the combined effect of first region 104, second region 108, and intervening tapered region 106 is a wide 3-dB bandwidth and a correspondingly high saturation current.

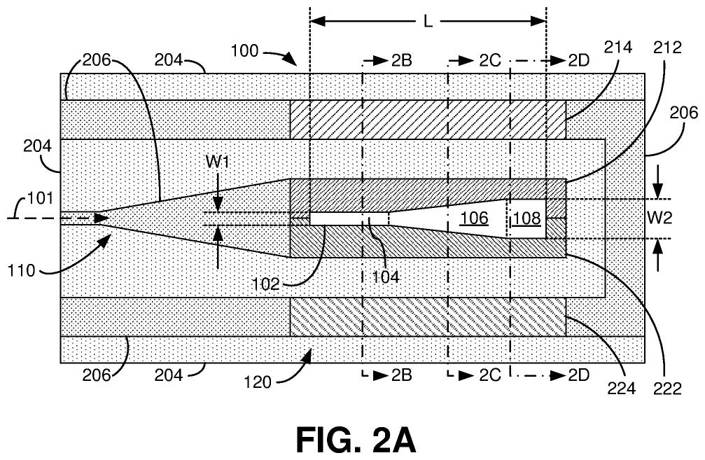

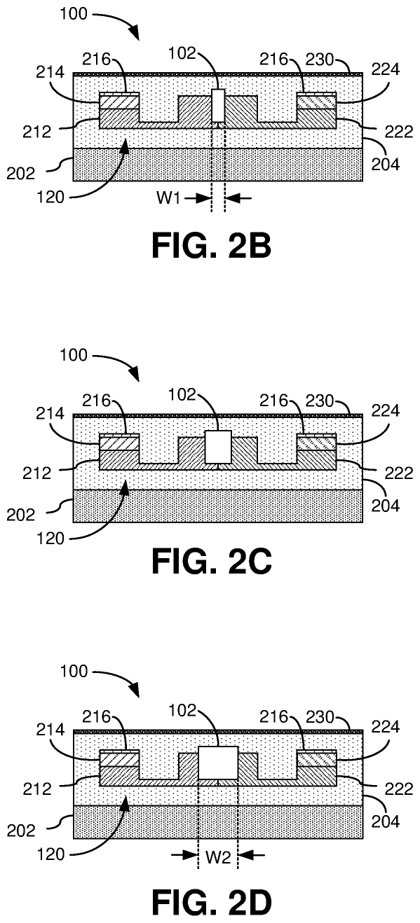

FIG. 2A is a plan view of some embodiments of a photodiode structure 100 employing a tapered light absorption structure 102, according to the present disclosure. In some embodiments, photodiode structure 100 may be adjacent and optically coupled to optical coupler structure 110 that receives input light 101 and provides that light toward an input end of light absorption structure 102 of photodiode structure 100. In some embodiments, optical coupler structure 110 may include a first semiconductor material (e.g., silicon (Si)). In some embodiments, optical coupler structure 110 may serve as a light spot size converter to convert from a first spot size associated with a waveguide (not explicitly depicted in FIG. 2A) to a second spot size associated with photodiode structure 100. However, other types of optical couplers not described herein may be employed to provide light (e.g., in the form of a photon signal) to photodiode structure 100. In some embodiments, optical coupler structure 110 and photodiode structure 100 may be at least partially surrounded or covered by an oxide layer 204 (e.g., silicon oxide (SiOₓ), such as silicon dioxide (SiO₂), or another oxide material).

Photodiode structure 100 may include light absorption structure 102 and doped structure 120. In some embodiments, doped structure 120 may include a first semiconductor material (e.g., silicon (Si), as may be employed in optical coupler structure 110), and light absorption structure 102 may include a second semiconductor material (e.g., germanium (Ge)). In some embodiments, photodiode structure 100 may be configured as a positive-intrinsic-negative (PIN) photodiode, in which doped structure 120 may provide the n-doped and p-doped semiconductor regions of the PIN photodiode, and light absorption structure 102 may provide the intrinsic semiconductor region of the PIN photodiode. In other embodiments, however, other photodetector structures may be employed using tapered light absorption structure 102.

Light absorption structure 102, as described above, may include first region 104, tapered region 106, and second region 108, in order from optical coupler structure 110. As illustrated in FIG. 2A, first region 104 may have a first constant width W1, and second region 108 may have a second constant width W2, with W2 being greater than W1. Further, tapered region 106 connecting first region 104 and second region 108 may have a first end adjacent first region 104, where the first end has a width equaling width W1 of first region 104. Tapered region 106 may also have a second end opposite the first end and adjacent second region 108, where the second end has a width equaling width W2 of second region 108. Also, in some embodiments, the width of tapered region 106 may vary linearly from width W1 to width W2 along the length of tapered region 106.

In some embodiments, widths W1 and W2, length L, and the length of each of first region 104, second region 108, and tapered region 106 may be chosen to provide a desired 3-dB bandwidth and/or level of saturation current. Factors that may be considered include, but are not limited to, the desired 3-dB bandwidth and/or saturation current, the semiconductor material used in light absorption structure 102, footprint restrictions in the IC device in which photodiode structure 100 is employed, and so on. In some embodiments, as shown in FIG. 2A, given overall length L for light absorption structure 102, first region 104 may have a length approximately 25-35% of length L, tapered region 106 may have a length approximately 45-55% of length L, and second region 108 may have a length approximately 15-25% of length L. Further, in some embodiments, length L may range from 10 microns (μm) to 20 μm, the length of first region 104 may range from 3 μm to 6 μm, the length of tapered region 106 may range from 5 μm to 10 μm, and the length of second region 108 may range from 2 μm to 4 μm. In some embodiments, width W1 may range from 0.3 μm to 0.6 μm, and width W2 may range from 0.5 μm to 1.0 μm.

Doped structure 120 may include a number of doped (e.g., p-doped and n-doped) regions of semiconductor material (e.g., silicon (Si)) that are aligned lengthwise along light absorption structure 102 (e.g., in parallel with a direction from which input light 101 is received). In some embodiments, such regions may include a first n-doped region 212, a first p-doped region 222, a second n-doped region 214, and a second p-doped region 224 that are formed within a semiconductor layer 206, which may be the same layer from which optical coupler structure 110 is fashioned. Further, in some embodiments, second n-doped region 214 and second p-doped region 224 may be more heavily doped than first n-doped region 212 and first p-doped region 222, respectively. As seen in the plan view of FIG. 2A, each of first n-doped region 212, first p-doped region 222, second n-doped region 214, and second p-doped region 224 may be aligned in parallel with the direction along which light absorption structure 102 is aligned.

FIGS. 2B through 2D illustrate structural side views of some embodiments of the photodiode structure 100 of FIG. 2A at corresponding positions denoted therein, according to the present disclosure. More specifically, FIG. 2B illustrates a cross-sectional view of photodiode structure 100 corresponding with first region 104 of light absorption structure 102. FIG. 2C illustrates a cross-sectional view of photodiode structure 100 corresponding with tapered region 106 of light absorption structure 102. FIG. 2D illustrates a cross-sectional view of photodiode structure 100 corresponding with second region 108 of light absorption structure 102. In some embodiments, first n-doped region 212 and first p-doped region 222 may laterally contact each other and may be U-shaped. Additionally, in some embodiments, second n-doped region 214 and second p-doped region 224 may be disposed on a portion of first n-doped region 212 and first p-doped region 222, respectively, separated from light absorption structure 102. Moreover, an overall thickness (in the vertical direction of FIGS. 2B through 2D) of each of light absorption structure 102 (e.g., including first region 104, tapered region 106, and second region 108), first n-doped region 212, first p-doped region 222, second n-doped region 214, and second p-doped region 224 may be constant. Other configurations for first n-doped region 212, first p-doped region 222, second n-doped region 214, and second p-doped region 224 other than those illustrated in FIGS. 2A through 2D are also possible in other embodiments.

Moreover, in some embodiments, as depicted in FIGS. 2B through 2D, a silicide layer 216 may be formed on each of second n-doped region 214 and second p-doped region 224 to facilitate a low contact resistance between each of second n-doped region 214 and second p-doped region 224 and corresponding conductive contact structures (not shown in FIGS. 2A through 2D) that may be subsequently formed thereon, as discussed more fully below.

As shown in each of FIGS. 2B through 2D, light absorption structure 102 and doped structure 120 may be disposed within one or more oxide layers 204 over a substrate 202 (e.g., a silicon (Si) substrate). Additionally, in some embodiments, a contact etch stop layer 230 may be disposed over oxide layer 204. Additional layers and/or structures may be included in an IC device that includes photodiode structure 100 in other embodiments, as described in greater detail below.

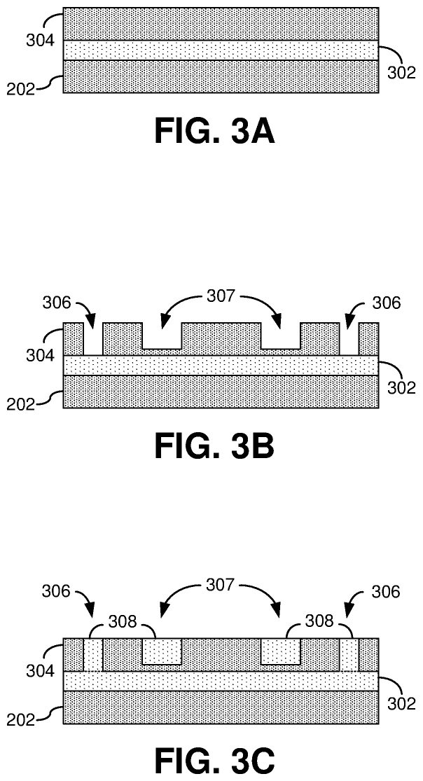

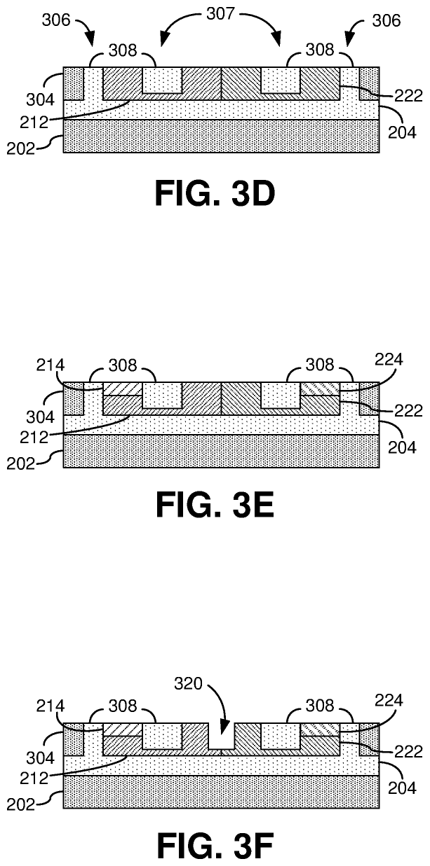

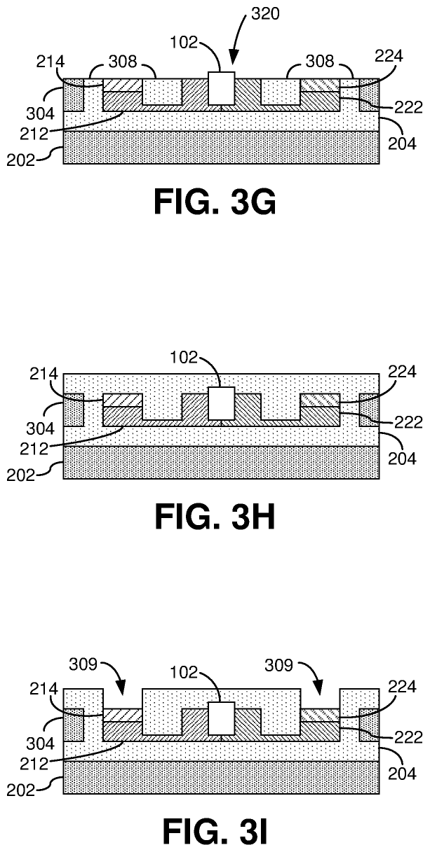

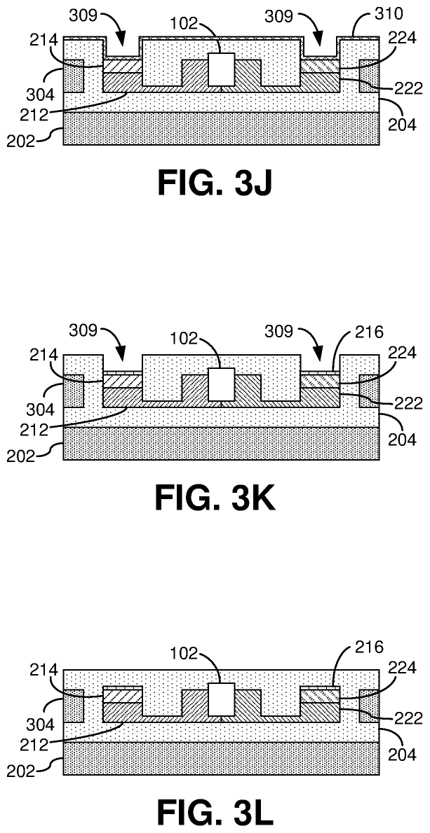

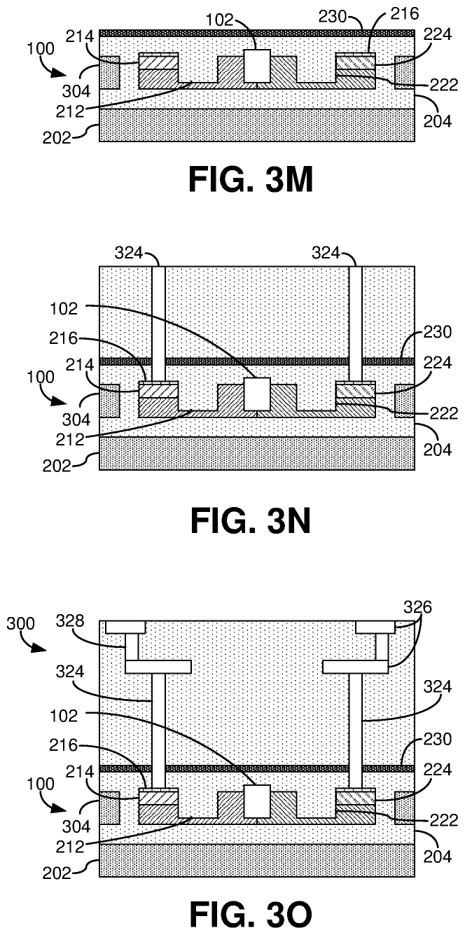

FIGS. 3A through 3O illustrate cross-sectional views of some embodiments of an IC device 300 including a photodiode structure 100 employing a tapered light absorption structure 102 at multiple stages of fabrication, according to the present disclosure. In some embodiments, FIGS. 3A through 3O represent stages of fabrication of photodiode structure 100 at the cross-section at tapered region 106 corresponding with FIG. 2C discussed above. Although FIGS. 3A through 3O are described as a series of acts, it will be appreciated that these acts are not limiting in that the order of the acts within each series can be altered in other embodiments, and the methods disclosed are also applicable to other structures. In other embodiments, some acts that are illustrated and/or described may be omitted in whole or in part.

For example, FIG. 3A illustrates a substrate 202 (e.g., a silicon (Si) substrate) over which a first oxide layer 302 (e.g., a bottom oxide layer or buried oxide layer) is formed (e.g., deposited). In some embodiments, first oxide layer 302 may include silicon oxide (SiOₓ), such as silicon dioxide (SiO₂), or another oxide or dielectric material. In turn, FIG. 3A also illustrates the forming (e.g., deposition) of a semiconductor layer 304 (e.g., another layer of silicon (Si) or another semiconductor material) over first oxide layer 302.

FIG. 3B illustrates the forming (e.g., photolithography and associated etching) of trenches 306 and trenches 307 in semiconductor layer 304. As depicted in FIG. 3B, trenches 306 may extend downward to at least an upper surface of first oxide layer 302. In some embodiments, trenches 307 may extend partway into semiconductor layer 304 and not extend to first oxide layer 302. In some embodiments, trenches 306, when formed, may isolate a portion of semiconductor layer 304 from a remainder of semiconductor layer 304 in the cross-sectional view of FIG. 3B, where the isolated portion will be employed in photodiode structure 100.

FIG. 3C illustrates the forming (e.g., deposition) of an oxide material 308 in trenches 306 and 307 of semiconductor layer 304. In some embodiments, oxide material 308 may include the same material as first oxide layer 302 (e.g., silicon oxide (SiOₓ), such as silicon dioxide (SiO₂), or another oxide or dielectric material). Further, in some embodiments, the deposition of oxide material 308 may be performed using chemical vapor deposition (CVD) (e.g., high-density plasma (HDP) CVD). Further, in some embodiments, the deposition of oxide material 308 may be followed by a planarization process (e.g. chemical-mechanical planarization (CMP)) to produce a smooth upper surface of semiconductor layer 304 and oxide material 308.

FIG. 3D illustrates the forming (e.g., implantation) of first n-doped region 212 and first p-doped region 222 in semiconductor layer 304. In some embodiments, as illustrated in FIG. 3D, first n-doped region 212 and first p-doped region 222 contact each other laterally in semiconductor layer 304 between and parallel to trenches 306 that are filled with oxide material 308. Moreover, in some embodiments, in the cross-sectional view of FIG. 3D, first n-doped region 212 and first p-doped region 222 may be U-shaped due to trenches 307 filled with oxide material 308.

FIG. 3E illustrates the forming (e.g., implantation) of second n-doped region 214 in first n-doped region 212 and second p-doped region 224 in first p-doped region 222. In some embodiments, second n-doped region 214 is formed at an upper region of a portion of first n-doped region 212 laterally adjacent oxide material 308, and second p-doped region 224 is formed at an upper region of a portion of first p-doped region 222 laterally adjacent oxide material 308. Consequently, in some embodiments, second n-doped region 214 and second p-doped region 224 are aligned in parallel with first n-doped region 212 and first p-doped region 222. Further, in some embodiments, second n-doped region 214 may more heavily doped (e.g., additionally doped) relative to first n-doped region 212, and second p-doped region 224 may be more heavily dopes (e.g., additionally doped) relative to first p-doped region 222.

FIG. 3F illustrates the forming (e.g., photolithography and associated etching) of a trench 320 along and into first n-doped region 212 and first p-doped region 222 (e.g., for subsequent formation of light absorption structure 102). As indicated above, FIGS. 3A through 3O, and particularly FIGS. 3F through 3O, depict cross-sectional views associated with the cross-sectional view of FIG. 2C corresponding to tapered region 106 of light absorption structure 102. Accordingly, in FIG. 3F, the width of trench 320 may be some width between first width W1 and second width W2. Consequently, the width of trench 320 in other cross-sectional views may vary depending on the location along trench 320. For example, in a portion of trench 320 associated with first region 104, the width of trench 320 may be first width W1. Accordingly, in a portion of trench 320 associated with second region 108, the width of trench 320 may be between second width W2.

FIG. 3G illustrates the forming (e.g., epitaxial growth) of a second semiconductor material (e.g., germanium (Ge)) in trench 320 to create light absorption structure 102. As illustrate in FIG. 3G, light absorption structure 102 may extend above a top surface of first n-doped region 212 and first p-doped region 222. In a plan view, light absorption structure 102 may be as illustrated in FIG. 2A, as described above, including first region 104, tapered region 106, and second region 108.

FIG. 3H illustrates the forming (e.g., deposition) of a second oxide layer 204 over light absorption structure 102, second n-doped region 214, second p-doped region 224, and surrounding structures. In some embodiments, second oxide layer 204 may include the same material as first oxide layer 302 (e.g., silicon oxide (SiOₓ), such as silicon dioxide (SiO₂), or another oxide or dielectric material).

FIG. 3I illustrates the removal (e.g., photolithography and associated etching) of trenches 309 of second oxide layer 204 over second n-doped region 214 and second p-doped region 224.

FIG. 3J illustrates the forming (e.g., deposition) of a silicidation metal layer 310 over second oxide layer 204, second n-doped region 214, and second p-doped region 224. In some embodiments, silicidation metal layer 310 may include nickel (Ni), cobalt (Co), or another metal suitable for a silicidation process.

FIG. 3K illustrates the forming (e.g., silicidation) of silicide layers 216 on second n-doped region 214 and second p-doped region 224 using silicidation metal layer 310. In some embodiments, silicidation metal layer 310 is thermally treated (e.g., heated at temperatures between 300 degrees Celsius (° C.) and 500° C.) so that silicidation metal layer 310 reacts with second n-doped region 214 and second p-doped region 224, but not second oxide layer 204, to form silicide layers 216. In some embodiments, the remnants of silicidation metal layer 310 that do not react with second n-doped region 214 and second p-doped region 224 may be cleaned (e.g., rinsed with a cleaning agent). In some embodiments, silicide layers 216 facilitate low-resistance connections between second n-doped region 214 and second p-doped region 224 and a subsequent conductive material to be formed thereon to increase the conductivity of a connection between second n-doped region 214 and a subsequently formed conductive contact structure, and between second p-doped region 224 and another conductive contact structure, as described below.

FIG. 3L illustrates the forming (e.g., deposition) of additional oxide material over silicide layers 216 to replace the oxide material that was etched prior to the deposition of silicidation metal layer 310, as depicted in FIG. 3J.

FIG. 3M illustrates the forming (e.g., deposition) of a contact etch stop layer 230 over second oxide layer 204 (e.g., in preparation for subsequent processing operations of the IC device in which photodiode structure 100 is employed). In some embodiments, contact etch stop layer 230 may include, but is not limited to, silicon nitride (SiN), silicon carbide (SiC), silicon carbonitride (SiCN), or the like.

FIG. 3N illustrates the forming (e.g., deposition) of an additional oxide layer 204 (e.g., silicon oxide (SiOₓ), such as silicon dioxide (SiO₂), or another oxide or dielectric material) on contact etch stop layer 230, followed by forming (e.g., etching and deposition) of conductive contact structures 324 through oxide layers 204 and contact etch stop layer 230 to contact silicide layers 216, thus providing an electrical connection via conductive contact structures 324 to second n-doped region 214 and second p-doped region 224. Conductive contact structures 324 may include, but are not limited to, copper (Cu) or another metal, metal alloy, or other conductive material.

FIG. 3O illustrates the forming (e.g., deposition) of one or more additional oxide layers 204 (e.g., silicon oxide (SiOₓ), such as silicon dioxide (SiO₂), or another oxide or dielectric material), followed by forming (e.g., etching and deposition) of conductive structures 326 and interconnecting vias 328 through one or more additional oxide layers 204 to electrically connect to conductive contact structures 324, thus providing conductive connections from other circuits (not shown in FIG. 3O) within an IC device 300 to second n-doped region 214 and second p-doped region 224. Conductive structures 326 and interconnecting vias 328 may include, but are not limited to, copper (Cu) or another metal, metal alloy, or other conductive material. While two layers of conductive structures 326 and one level of interconnecting vias 328 are depicted in FIG. 3O, other numbers of conductive structures 326 and interconnecting vias 328 may be employed in other embodiments.

Within IC device 300, the use of a tapered profile for light absorption structure 102, as discussed above, may facilitate both high-power and high-speed performance for corresponding photodiode structure 100. Moreover, as described above in conjunction with FIGS. 3A through 3O, the fabrication of light absorption structure 102 and associated photodiode structure 100 may not necessitate the use of highly specialized or complex photolithography, etching, deposition, or similar IC-related manufacturing processes.

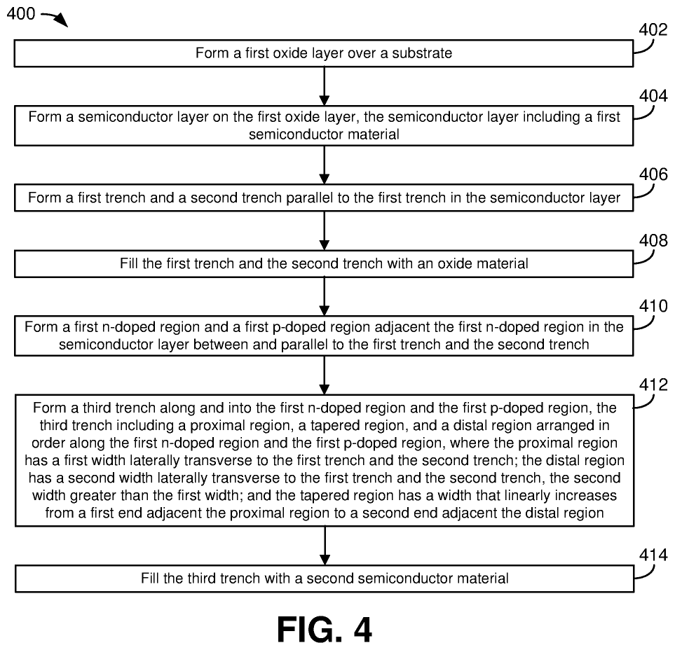

FIG. 4 illustrates some embodiments of a methodology 400 of forming IC device 300, including photodiode structure 100, of FIGS. 3A through 3O, in accordance with the present disclosure. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At Act 402, for example, a first oxide layer (e.g., first oxide layer 302 of FIG. 3A) may be formed over a substrate (e.g., substrate 202 of FIG. 3A). At Act 404, a semiconductor layer (e.g., semiconductor layer 304 of FIG. 3A) may be formed on the first oxide layer. FIG. 3A illustrates a cross-sectional view of some embodiments corresponding to Act 402 and Act 404.

At Act 406, a first trench and a second trench parallel to the first trench (e.g., trenches 306 of FIG. 3B) may be formed in the semiconductor layer. FIG. 3B illustrates a cross-sectional view of some embodiments corresponding to Act 406.

At Act 408, the first trench and the second trench may be filled with an oxide material (e.g., oxide material 308 of FIG. 3C). FIG. 3C illustrates a cross-sectional view of some embodiments corresponding to Act 408.

At Act 410, a first n-doped region (e.g., first n-doped region 212 of FIG. 3D) and a first p-doped region (e.g., first p-doped region 222 of FIG. 3D) adjacent the first n-doped region may be formed in the semiconductor structure between and parallel to the first trench and the second trench. FIG. 3D illustrates a cross-sectional view of some embodiments corresponding to Act 410.

At Act 412, a third trench (e.g., trench 320 of FIG. 3F) may be formed along and into the first n-doped region and the first p-doped region. The third trench may include a proximal region (e.g., associated with first region 104 of FIG. 2A), a tapered region (e.g., associated with tapered region 106 of FIG. 2A), and a distal region (e.g., associated with second region 108 of FIG. 2A) arranged in order along the first n-doped region and the first p-doped region. The proximal region may have a first width (e.g., first width W1 of FIG. 2A) laterally transverse to the first trench and the second trench. The distal region may have a second width (e.g., second width W2 of FIG. 2A) laterally transverse to the first trench and the second trench, where the second width may be greater than the first width. The tapered region may have a width that linearly increases from a first end adjacent the proximal region to a second end adjacent the distal region. FIG. 3F illustrates a cross-sectional view of some embodiments corresponding to Act 412.

At Act 414, the third trench may be filled with a second semiconductor material (e.g., a semiconductor material, such as germanium (Ge), for light absorption structure 102 of FIG. 2A). FIG. 3G illustrates a cross-sectional view of some embodiments corresponding to Act 414.

Some embodiments relate to an integrated circuit (IC) device. The device includes: an optical waveguide structure over a substrate; and a photodiode structure over the substrate and laterally adjacent the optical waveguide structure, the photodiode structure including: a doped structure including a first semiconductor material, and a light absorption structure including a second semiconductor material and contacting the doped structure, the light absorption structure aligned with the optical coupler structure along a direct, the light absorption structure including: a first region proximal to the optical waveguide structure, the first region having a first width transverse to the direction; a second region distal from the optical waveguide structure, the second region having a second width transverse to the direction, the second width greater than the first width; and a tapered region connecting the first region to the second region, the tapered region having a first end adjacent the first region and a second end adjacent the second region, the first end having the first width transverse to the direction, and the second end having the second width transverse to the direction.

Some embodiments relate to another IC device. The device includes: an optical waveguide structure over a substrate; and a photodiode structure over the substrate and laterally adjacent the optical waveguide structure along a direction from the optical waveguide structure, the photodiode structure including a light absorption structure, the light absorption structure including a proximal region, a tapered region, and a distal region arranged in order along the direction from the optical waveguide structure, where the proximal region has a first width laterally transverse to the direction; the distal region has a second width laterally transverse to the direction, the second width greater than the first width; and the tapered region has a width that linearly increases from a first end adjacent the proximal region to a second end adjacent the distal region.

Some embodiments relate to a method. The method includes: forming a first oxide layer over a substrate; forming a semiconductor layer on the first oxide layer, the semiconductor layer including a first semiconductor material; forming a first trench and a second trench parallel to the first trench in the semiconductor layer; filling the first trench and the second trench with an oxide material; forming a first n-doped region and a first p-doped region adjacent the first n-doped region in the semiconductor layer between and parallel to the first trench and the second trench; forming a third trench along and into the first n-doped region and the first p-doped region, the third trench including a proximal region, a tapered region, and a distal region arranged in order along the first n-doped region and the first p-doped region, where the proximal region has a first width laterally transverse to the first trench and the second trench; the distal region has a second width laterally transverse to the first trench and the second trench, the second width greater than the first width; and the tapered region has a width that linearly increases from a first end adjacent the proximal region to a second end adjacent the distal region; and filling the third trench with a second semiconductor material.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device, comprising:
an optical coupler structure over a substrate; and
a photodiode structure over the substrate and laterally adjacent the optical coupler structure, the photodiode structure comprising:
a doped structure comprising a first semiconductor material, and
a light absorption structure comprising a second semiconductor material and contacting the doped structure, the light absorption structure aligned with the optical coupler structure along a direction, the light absorption structure including:
a first region proximal to the optical coupler structure, the first region having a first width transverse to the direction;
a second region distal from the optical coupler structure, the second region having a second width transverse to the direction, the second width greater than the first width; and
a tapered region connecting the first region to the second region, the tapered region having a first end adjacent the first region and a second end adjacent the second region, the first end having the first width transverse to the direction, and the second end having the second width transverse to the direction.

2. The IC device of claim 1, the first semiconductor material comprising silicon, and the second semiconductor material comprising germanium.

3. The IC device of claim 1, the doped structure comprising:
a first n-doped region aligned parallel to the direction and in contact with a first side of the light absorption structure; and
a first p-doped region aligned parallel to the direction and in contact with a second side of the light absorption structure opposite the first side.

4. The IC device of claim 3, the doped structure further comprising:
a second n-doped region on a portion of the first n-doped region; and
a second p-doped region on a portion of the first p-doped region.

5. The IC device of claim 4, wherein:
the second n-doped region is more heavily doped than the first n-doped region; and
the second p-doped region is more heavily doped than the first p-doped region.

6. The IC device of claim 4, further comprising:
a first conductive contact structure disposed over and electrically coupled to the second n-doped region; and
a second conductive contact structure disposed over and electrically coupled to the second p-doped region.

7. The IC device of claim 6, further comprising:
a first silicide layer connecting the first conductive contact structure to the second n-doped region; and
a second silicide layer connecting the second conductive contact structure to the second p-doped region.

8. The IC device of claim 1, the first region, the second region, and the tapered region of the the light absorption structure having a same thickness transverse to the first width, the second width, and the direction.

9. The IC device of claim 1, wherein:
a length of the light absorption structure along the direction lies in a range from 10 microns to 20 microns;
the first width lies in a range from 0.3 microns to 0.6 microns; and
the second width lies in a range from 0.5 microns to 1.0 microns.

10. An integrated circuit (IC) device, comprising:
an optical coupler structure over a substrate; and
a photodiode structure over the substrate and laterally adjacent the optical coupler structure along a direction from the optical coupler structure, the photodiode structure comprising a light absorption structure, the light absorption structure comprising a proximal region, a tapered region, and a distal region arranged in order along the direction from the optical coupler structure, wherein:
the proximal region has a first width laterally transverse to the direction;
the distal region has a second width laterally transverse to the direction, the second width greater than the first width; and
the tapered region has a width that linearly increases from a first end adjacent the proximal region to a second end adjacent the distal region.

11. The IC device of claim 10, wherein:
the proximal region has a length along the direction that lies in a range of 25 percent to 35 percent of a length of the light absorption structure along the direction;
the distal region has a length along the direction that lies in a range of 15 percent to 25 percent of the length of the light absorption structure along the direction; and
the tapered region has a length along the direction that lies in a range of 45 percent to 55 percent of the length of the light absorption structure along the direction.

12. The IC device of claim 10, the photodiode structure further comprising a doped structure in contact with the light absorption structure and comprising a first semiconductor material, the light absorption structure comprising a second semiconductor material different from the first semiconductor material.

13. The IC device of claim 12, the first semiconductor material comprising silicon, and the second semiconductor material comprising germanium.

14. The IC device of claim 12, the doped structure comprising:
a first n-doped region aligned parallel to the direction and in contact with a first side of the light absorption structure;
a second n-doped region on a portion of the first n-doped region, the second n-doped region more heavily doped that the first n-doped region;
a first p-doped region aligned parallel to the direction and in contact with a second side of the light absorption structure opposite the first side; and
a second p-doped region on a portion of the first p-doped region, the second p-doped region more heavily doped than the first p-doped region.

15. A method, comprising:
forming a first oxide layer over a substrate;
forming a semiconductor layer on the first oxide layer, the semiconductor layer comprising a first semiconductor material;
forming a first trench and a second trench parallel to the first trench in the semiconductor layer;
filling the first trench and the second trench with an oxide material;
forming a first n-doped region and a first p-doped region adjacent the first n-doped region in the semiconductor layer between and parallel to the first trench and the second trench;
forming a third trench along and into the first n-doped region and the first p-doped region, the third trench comprising a proximal region, a tapered region, and a distal region arranged in order along the first n-doped region and the first p-doped region, wherein:
the proximal region has a first width laterally transverse to the first trench and the second trench;
the distal region has a second width laterally transverse to the first trench and the second trench, the second width greater than the first width; and
the tapered region has a width that linearly increases from a first end adjacent the proximal region to a second end adjacent the distal region; and
filling the third trench with a second semiconductor material.

16. The method of claim 15, further comprising:
forming a fourth trench and a fifth trench in the semiconductor layer between and parallel to the first trench and the second trench, the fourth trench being closer than the fifth trench to the first trench; and
filling the fourth trench and the fifth trench with the oxide material while filling the first trench and the second trench.

17. The method of claim 16, further comprising:
forming a second n-doped region in an upper portion of the first n-doped region between the first trench and the fourth trench; and
forming a second p-doped region in an upper portion of the first p-doped region between the fifth trench and the second trench.

18. The method of claim 17, further comprising:
forming a second oxide layer over the semiconductor layer, the first n-doped region, the first p-doped region, the second n-doped region, the second p-doped region, and the second semiconductor material;
etching a portion of the second oxide layer over the second n-doped region and the second p-doped region;
forming a first silicide layer on the second n-doped region and a second silicide layer on the second p-doped region; and
reforming the second oxide layer over the first silicide layer and the second silicide layer.

19. The method of claim 18, further comprising:
forming a first conductive contact structure through the second oxide layer to the first silicide layer; and
forming a second conductive contact structure through the second oxide layer to the second silicide layer.

20. The method of claim 15, wherein the first semiconductor material comprises silicon, and the second semiconductor material comprises germanium.
